(19) United States
(12) Patent Application Publication
(10) Pub. No.: US 2016/0130462 A1
(43) Pub. Date: May 12, 2016

(54) TOPCOAT COMPOSITIONS AND PHOTOLITHOGRAPHIC METHODS

(71) Applicant: Rohm and Haas Electronic Materials LLC, Marlborough, MA (US)

(72) Inventors: Cong LIU, Shrewsbury, MA (US); Doris H. KANG, Shrewsbury, MA (US); Deyan WANG, Hudson, MA (US); Cheng-Bai XU, Southborough, MA (US); Mingqi LI, Shrewsbury, MA (US)

(21) Appl. No.: 14/929,533

(22) Filed: Nov. 2, 2015

Related U.S. Application Data
(60) Provisional application No. 62/076,902, filed on Nov. 7, 2014.

(51) Int. Cl. C09D 133/16; G03F 7/11; G03F 7/20

(52) U.S. Cl. CPC C09D 133/16; G03F 7/2041; G03F 7/11

(57) ABSTRACT

A topcoat composition comprises: a matrix polymer; a surface active polymer comprising: a first unit comprising a group of the following general formula (I):

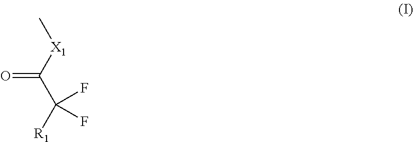

wherein R₁ represents H, F, C1 to C8 alkyl or C1 to C8 fluoroalkyl, optionally comprising one or more heteroatom; X₁ represents oxygen, sulfur or NR₂, wherein R₂ is chosen from hydrogen and optionally substituted C1 to C10 alkyl; and a solvent. The surface active polymer is present in the composition in an amount less than the matrix polymer, and the surface active polymer has a lower surface energy than a surface energy of the matrix polymer. The invention has particular applicability in photolithographic processes as a photoresist topcoat layer in the manufacture of semiconductor devices.

This application claims the benefit of priority under 35 U.S.C. §119(e) to U.S. Provisional Application No. 62/076,902, filed Nov. 7, 2014, the entire contents of which are incorporated herein by reference.

### FIELD

This invention relates to topcoat compositions that may be applied above a photoresist composition in a photolithographic process. The invention further relates to methods of forming patterns using the topcoat compositions. The invention finds particular applicability in the semiconductor manufacturing industry for forming semiconductor devices.

### BACKGROUND

Photoresists are photosensitive films used for transfer of an image to a substrate. A coating layer of a photoresist is formed on a substrate and the photoresist layer is then exposed through a photomask to a source of activating radiation. The photomask has areas that are opaque to the activating radiation and other areas that are transparent to the activating radiation. Exposure to activating radiation provides a photoinduced chemical transformation of the photoresist coating to thereby transfer the pattern of the photomask to the photoresist coated substrate. Following exposure, the photoresist is baked and developed by contact with a developer solution to provide a relief image that permits selective processing of the substrate.

One approach to achieving nanometer (nm)-scale feature sizes in semiconductor devices is to use shorter wavelengths of light. However, the difficulty in finding materials that are transparent below 193 nm has led to the immersion lithography process to increase the numerical aperture of the lens by use of a liquid to focus more light into the film. Immersion lithography employs a relatively high refractive index fluid between the last surface of an imaging device (e.g., KrF or ArF light source) and the first surface on the substrate, for example, a semiconductor wafer.

In immersion lithography, direct contact between the immersion fluid and photoresist layer can result in leaching of components of the photoresist into the immersion fluid. This leaching can cause contamination of the optical lens and bring about a change in the effective refractive index and transmission properties of the immersion fluid. In an effort to ameliorate this problem, use of a topcoat layer over the photoresist layer as a barrier between the immersion fluid and underlying photoresist layer has been proposed. The use of topcoat layers in immersion lithography, however, presents various challenges. Topcoat layers can affect, for example, the process window, critical dimension (CD) variation and resist profile depending on characteristics such as topcoat refractive index, thickness, acidity, chemical interaction with the resist and soaking time. In addition, use of a topcoat layer can negatively impact device yield due, for example, to micro-bridging defects which prevent proper resist pattern formation.

To improve performance of topcoat materials, the use of self-segregating topcoat compositions to form a graded topcoat layer has been proposed, for example, in Self-segregating Materials for Immersion Lithography, Daniel P. Sanders et al., Advances in Resist Materials and Processing Technology XXV, Proceedings of the SPIE, Vol. 6923, pp. 692309-1-692309-12 (2008). A self-segregated topcoat would theoretically allow for a tailored material having desired properties at both the immersion fluid and photoresist interfaces, for example, an improved water receding contact angle at the immersion fluid interface and good developer solubility at the photoresist interface.

Topcoats exhibiting a low receding contact angle for a given scan speed can result in water mark defects. These defects are generated when water droplets are left behind as the exposure head moves across the wafer. As a result, resist sensitivity becomes altered due to leaching of resist components into the water droplets, and water can permeate into the underlying resist. Topcoats having high receding contact angles would therefore be desired to allow for operation of immersion scanners at greater scan speeds, thereby allowing for increased process throughput. U.S. Patent App. Pub. Nos. 2007/0212646A1 to Gallagher et al. and 2010/0183976A1 to Wang et al. describe immersion topcoat compositions that include a self-segregating surface active polymer which allow for improved water receding contact angles. With the desire for increasingly faster scan speeds on the exposure tool to allow for increased throughput, topcoat compositions having improved receding contact angles are desired.

There is a continuing need in the art for topcoat compositions exhibiting high receding contact angles for use in immersion lithography, and for photolithographic methods making use of such materials.

### SUMMARY

In accordance with a first aspect of the application, provided are new topcoat compositions. The topcoat compositions comprise: a first unit comprising a group of the following general formula (I):

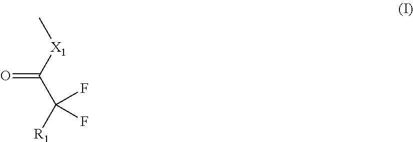

wherein R₁ represents H, F, C1 to C8 alkyl or C1 to C8 fluoroalkyl, optionally comprising one or more heteroatom; X₁ represents oxygen, sulfur or NR₂, wherein R₂ is chosen from hydrogen and optionally substituted C1 to C10 alkyl; and a solvent. The surface active polymer is present in the composition in an amount less than the matrix polymer, and the surface active polymer has a lower surface energy than a surface energy of the matrix polymer. The invention has particular applicability in photolithographic processes as a photoresist topcoat layer in the manufacture of semiconductor devices, with particular applicability in immersion lithography.

Also provided are coated substrates, comprising: a photoresist layer on a substrate; and a topcoat layer formed from a topcoat composition as described herein on the photoresist layer.

Also provided are pattern-forming methods. The methods comprise: (a) forming a photoresist layer over a substrate; (b) forming a topcoat layer over the photoresist layer, wherein the topcoat layer is formed from a topcoat composition as described herein; (c) exposing the topcoat layer and the photoresist layer to activating radiation; and (d) contacting the exposed topcoat layer and photoresist layer with a developer to form a photoresist pattern. In a preferred aspect, the exposing is conducted by immersion lithography.

As used herein: “g” means grams; “wt %” means weight percent; “L” means liter; “nm” means nanometer; “mm” means millimeter; “Å” means Angstrom; “mol %” means mole percent; “Mw” means weight average molecular weight; “Mn” means number average molecular weight; “PDI” means polydispersity index=Mw/Mn; “copolymer” is inclusive of polymers containing two or more different types of polymerized units; “alkyl” is inclusive of linear, branched and cyclic alkyl structures; “aliphatic” is inclusive of linear, branched and cyclic aliphatic structures; and the articles “a” and “an” are inclusive of one or more.

### DETAILED DESCRIPTION

### Topcoat Compositions

The topcoat compositions of the invention comprise a matrix polymer, a surface active polymer, a solvent, and can include one or more additional, optional components. The surface active polymer has a lower surface energy than that of the matrix polymer and other polymers in the composition.

Topcoat compositions of the invention that are applied above a photoresist layer are self-segregating, and can minimize or prevent migration of components of the photoresist layer into an immersion fluid employed in an immersion lithography process. As used herein, the term “immersion fluid” means a fluid, typically water, interposed between a lens of an exposure tool and a photoresist coated substrate to conduct immersion lithography.

Also as used herein, a topcoat layer will be considered as inhibiting the migration of photoresist material into an immersion fluid if a decreased amount of acid or organic material is detected in the immersion fluid upon use of the topcoat composition relative to the same photoresist system that is processed in the same manner, but in the absence of the topcoat composition layer. Detection of photoresist material in the immersion fluid can be conducted through mass spectroscopy analysis of the immersion fluid before exposure to the photoresist (with and without the overcoated topcoat composition layer) and then after lithographic processing of the photoresist layer (with and without the overcoated topcoat composition layer) with exposure through the immersion fluid. Preferably, the topcoat composition provides at least a 10 percent reduction in photoresist material (e.g., acid or organics as detected by mass spectroscopy) residing in the immersion fluid relative to the same photoresist that does not employ any topcoat layer (i.e., the immersion fluid directly contacts the photoresist layer), more preferably the topcoat composition provides at least a 20, 50, or 100 percent reduction in photoresist material residing in the immersion fluid relative to the same photoresist that does not employ a topcoat layer.

Topcoat compositions of the invention can allow for improvement in one or more of various water contact angle characteristics that are important in an immersion lithography process, for example, static contact angle, receding contact angle, advancing contact angle and sliding angle at the immersion fluid interface. The topcoat layer compositions provide topcoat layers having excellent developer solubility for both exposed and unexposed regions of the layer, for example, in an aqueous base developer.

The compositions can be used in dry lithography or more typically in immersion lithography processes. The exposure wavelength is not particularly limited except by the photoresist compositions, with 248 nm or sub 200 nm such as 193 nm or an EUV wavelength (e.g., 13.4 nm) being typical.

The topcoat compositions of the invention include two or more different polymers. Polymers useful in the invention may be homopolymers, but more typically include a plurality of distinct repeat units, with two or three distinct units, i.e., copolymers or terpolymers, being typical. The polymers are preferably aqueous alkali soluble such that a topcoat layer formed from the composition can be removed in the resist development step using an aqueous alkaline developer, for example, a quaternary ammonium hydroxide solution, for example, tetra methyl ammonium hydroxide (TMAH).

A variety of polymers may be employed in the topcoat compositions of the invention, including polymers comprising polymerized acrylate groups, polyesters, and other repeat units and/or polymer backbone structures such as provided by, for example, poly(alkylene oxide), poly(meth)acrylic acid, poly (meth)acrylamides, polymerized aromatic (meth)acrylates, and polymerized vinyl aromatic monomers. Typically, the polymers each include at least two differing repeat units. The different polymers suitably may be present in varying relative amounts.

The polymers of the topcoat compositions of the invention may contain a variety of repeat units, including, for example, one or more: hydrophobic groups; weak acid groups; strong acid groups; branched optionally substituted alkyl or cycloalkyl groups; fluoroalkyl groups; or polar groups, such as ester, ether, carboxy, or sulfonyl groups. The presence of particular functional groups on the repeat units of the polymers will depend, for example, on the intended functionality of the polymer.

In certain preferred aspects, one or more polymers of the coating composition will comprise one or more groups that are reactive during lithographic processing, for example, one or more photoacid-acid labile groups that can undergo cleavage reactions in the presence of acid and heat, such as acid-labile ester groups (e.g., t-butyl ester groups such as provided by polymerization of t-butyl acrylate or t-butylmethacrylate, and tertiary cycloalkyl ester groups such as provided by polymerization of methyladamantyl(meth)acrylate, ethyladamantyl(meth)acrylate, methylcyclopentyl(meth)acrylate and ethylcyclopentyl(meth)acrylate) and/or acetal groups such as provided by polymerization of a vinyl ether compound. The presence of such groups can render the associated polymer(s) more soluble in a developer solution, thereby aiding in developability and removal of the topcoat layer during a development process.

The polymers can advantageously be selected to tailor characteristics of the topcoat layer, with each generally serving one or more purpose or function. Such functions include, for example, one or more of photoresist profile adjusting, topcoat surface adjusting, reducing defects and reducing interfacial mixing between the topcoat and photoresist layers.

The matrix polymer may include one or more repeating units, with two or more repeating units being typical. The matrix polymer should provide a sufficiently high developer dissolution rate for reducing overall defectivity due, for example, to micro-bridging. The matrix polymer may include, for example, a sulfonamide-containing monomer for enhancing the polymer developer dissolution rate. A typical developer dissolution rate for the matrix polymer is greater than 300 nm/second. The matrix polymers can be fluorinated or non-fluorinated. For some photoresist materials, fluorinated topcoat matrix polymers can reduce or minimize interfacial mixing between the topcoat layer and underlying photoresist layer. Accordingly, one or more repeating unit of the matrix polymer can be fluorinated, for example, with a fluoroalkyl group such as a C1 to C4 fluoroalkyl group, typically fluoromethyl, and may be present, for example, as a sulfonamide group (e.g., —NHSO₂CF₃) or a fluoroalcohol group (e.g., —C(CF₃)₂OH).

The matrix polymer has a higher surface energy than that of, and is preferably immiscible with, the additive polymer, to allow the additive polymer to phase separate from the matrix polymer and migrate to the upper surface of the overcoat layer away from the topcoat photoresist interface. The surface energy of the matrix polymer is typically from 30 to 60 mN/m.

Exemplary matrix polymers in accordance with the invention include the following:

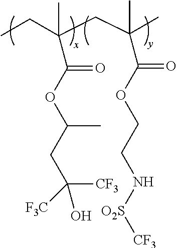

wherein x is from 0 to 90 wt % (weight percent) and y is from 10 to 100 wt %, based on the weight of the polymer. In an exemplary first matrix polymer, x/y is 90/10 wt %;

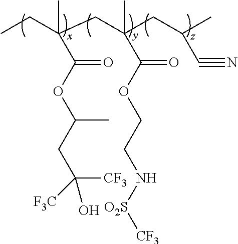

wherein x is from 0 to 85 wt %, y is from 10 to 80 wt % and z is from 5 to 20 wt % based on the weight of the polymer. In an exemplary matrix polymer, x/y/z are 40/45/15 wt %;

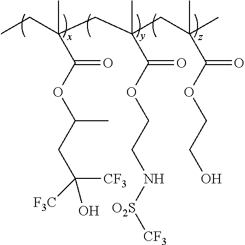

wherein x is from 0 to 85 wt %, y is from 10 to 80 wt % and z is from 5 to 20 wt % based on the weight of the polymer. In an exemplary matrix polymer, x/y/z are 40/45/15 wt %.

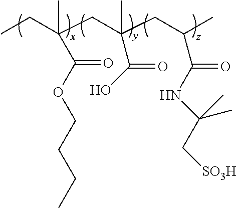

wherein x is from 50 to 85 wt %, y is from 0 to 80 wt % and z is from 0 to 25 wt % based on the weight of the polymer. In exemplary matrix polymers, x/y/z are 57/39/3 wt % and 48/52/0 mol %.

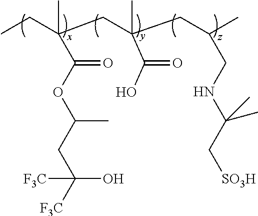

wherein x is from 50 to 85 wt %, y is from 0 to 80 wt % and z is from 0 to 25 wt % based on the weight of the polymer. In an exemplary matrix polymer, x/y/z are 60/30/10 wt %.

The matrix polymer is typically present in the compositions in an amount of from 70 to 99 wt %, more typically from 85 to 95 wt %, based on total solids of the topcoat composition. The weight average molecular weight of the matrix polymer is typically less than 400,000, for example, from 5000 to 50,000 or from 5000 to 25,000.

The surface active polymer is provided in the topcoat compositions to improve surface properties at the topcoat/immersion fluid interface. In particular, the surface active polymer beneficially can provides desirable surface properties with respect to water, for example, one or more of improved static contact angle (SCA), receding contact angle (RCA), advancing contact angle (ACA) and sliding angle (SA) at the topcoat/immersion fluid interface. In particular, the surface active polymer can allow higher RCAs, which can allow for faster scanning speeds and increased process throughput. A layer of the topcoat composition in a dried state typically has a water receding contact angle of from 75 to 90°. The phrase “in a dried state” means containing 8 wt % or less of solvent, based on the entire composition.

The surface active polymer is preferably aqueous alkali soluble. The surface active polymer has a lower surface energy than the matrix polymer. Preferably, the surface active polymer has a significantly lower surface energy than and is substantially immiscible with the matrix polymer, as well as other polymers present in the overcoat composition. In this way, the topcoat composition can be self-segregating, wherein the surface active polymer migrates to the upper surface of the topcoat layer apart from other polymers during coating. The resulting topcoat layer is thereby rich in the surface active polymer at the topcoat layer upper surface at the topcoat//immersion fluid interface in the case of an immersion lithography process. While the desired surface energy of the surface active polymer will depend on the particular matrix polymer and its surface energy, the surface active polymer surface energy is typically from 15 to 35 mN/m, preferably from 18 to 30 mN/m. The surface active polymer is typically from 5 to 25 mN/m less than that of the matrix polymer, preferably from 5 to 15 mN/m less than that of the matrix polymer.

The surface active polymer includes a first unit containing a group of the following general formula (I):

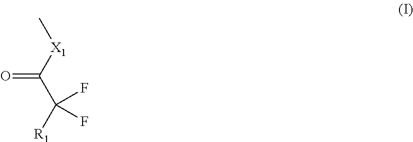

wherein R₁ represents H, F, C1 to C8 alkyl or C1 to C8 fluoroalkyl, preferably perfluorinated alkyl; X₁ represents oxygen, sulfur or NR₂, wherein R₂ is chosen from hydrogen and optionally substituted C1 to C10 alkyl, with oxygen being preferred.

In accordance with a preferred aspect, the first unit is of the following general formula (II):

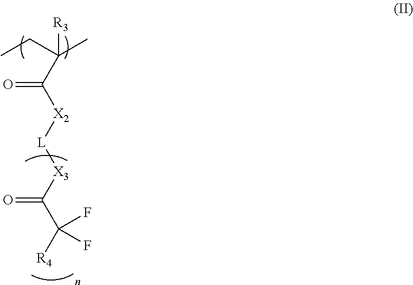

wherein: R₃ represents H, F, C1 to C4 alkyl or C1 to C4 fluoroalkyl; R₄ independently represents H, F, C1 to C8 alkyl or C1 to C8 fluoroalkyl, preferably perfluorinated alkyl, optionally including one or more heteroatom such as oxygen and/or sulfur; X₂ and X₃ independently represent oxygen, sulfur or NR₅, wherein R₅ is chosen from hydrogen and optionally substituted C1 to C10 alkyl; L represents an (n+1) valent linker, for example, chosen from optionally substituted aliphatic, such as C1 to C6 linear, branched or cyclic alkylene, with branched or cyclic being preferred, and aromatic hydrocarbons, and combinations thereof, optionally with one or more linking moiety chosen from —O—, —S—, —COO— and —CONR₆— wherein R₆ is chosen from hydrogen and optionally substituted C1 to C10 alkyl, such as C2 to C6 alkyl; and n is an integer from 1 to 5. In general formula (II), n is preferably 2 as this can have the effect of providing decreased surface energy and creating a hydrophobic surface which can be useful for enhancing surface properties of the resulting topcoat layer with respect to water.

Units containing a group of general formula (I) such as those of general formula (II) are typically present in the surface active polymer in an amount of from 50 to 100 mol %, for example, from 70 to 100 mol %, from 80 to 100 mol %, from 90 to 100 mol % or 100 mol %, based on the surface active polymer. Exemplary suitable monomers for the units of general formula (II) include the following:

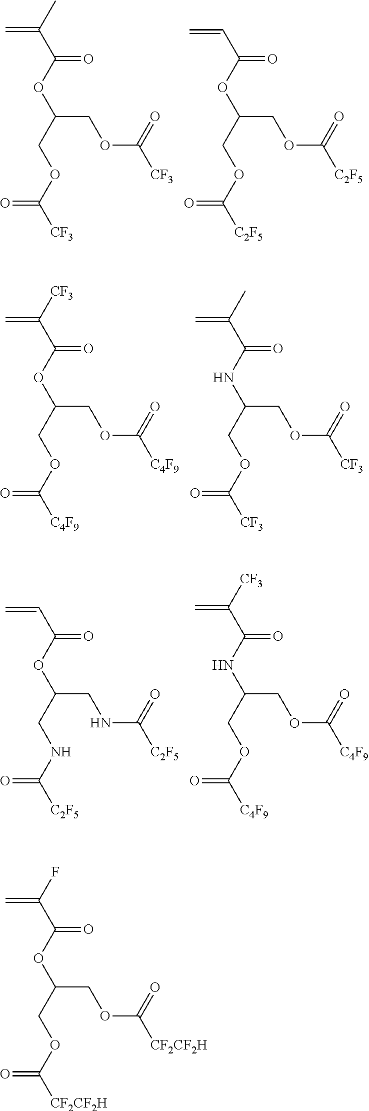

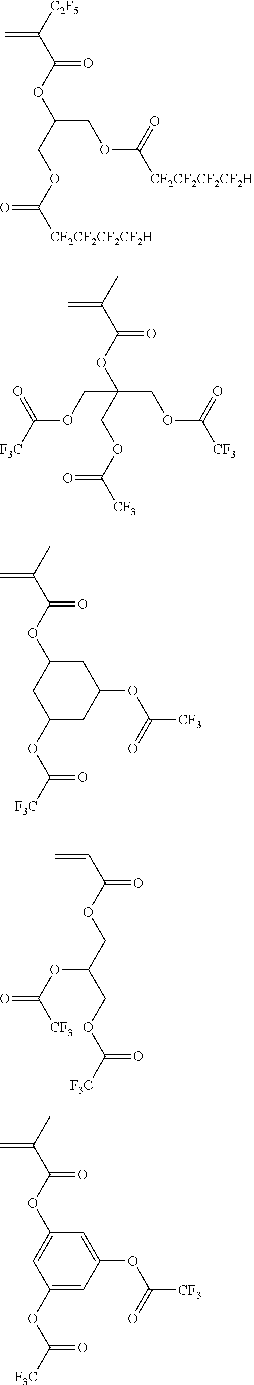

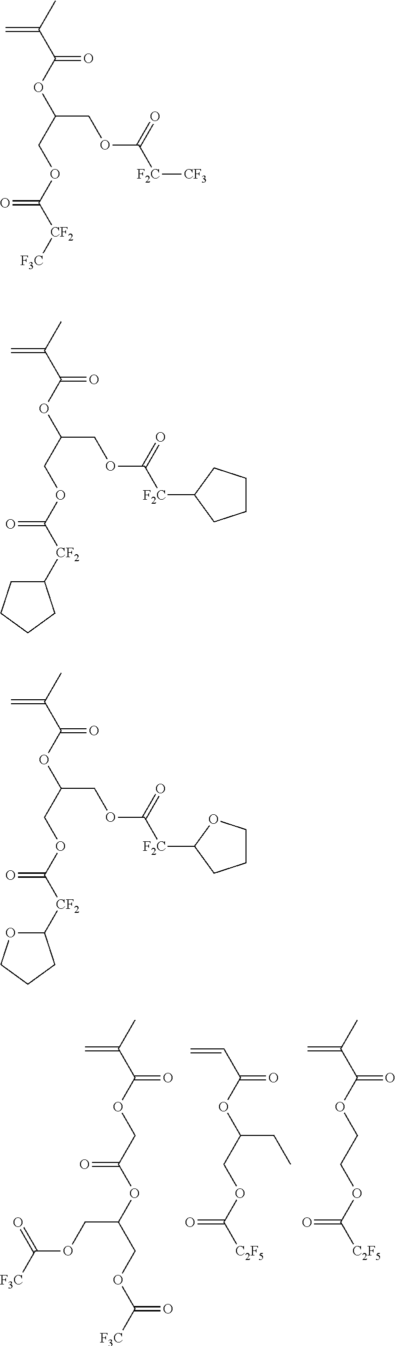

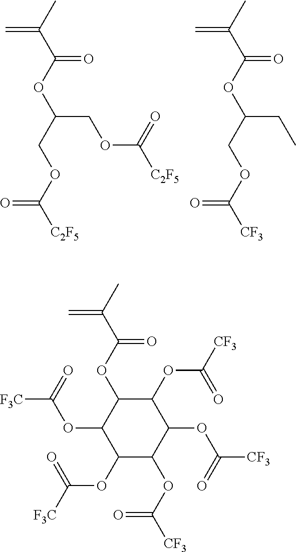

The surface active polymer can include one or more additional types of units. It is preferable, for example, for the surface active polymer to include one or more additional unit comprising fluorine, such as units chosen from one or more of fluorinated sulfonamide groups, fluorinated alcohol groups, fluorinated ester groups, and acid labile leaving groups and combinations thereof.

Preferable fluorinated sulfonamide units for the surface active polymer include, for example, those formed a monomer of the following general formula (III):

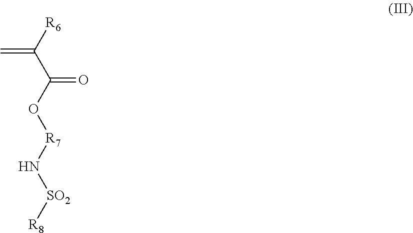

wherein: R₆ is hydrogen or a C1 to C6 alkyl, preferably methyl, or fluoroalkyl group; R₇ is a C1 to C8 alkylene group, preferably branched, for example having one, two or more branched carbon atoms; and R₈ is a C1 to C4 fluoroalkyl group such as fluoromethyl or fluoroethyl. It is believed that such fluorinated sulfonamide-containing units can provide improved dark field developer dissolution rate while maintaining a high receding contact angle. Suitable monomers of general formula (III) include, for example, the following:

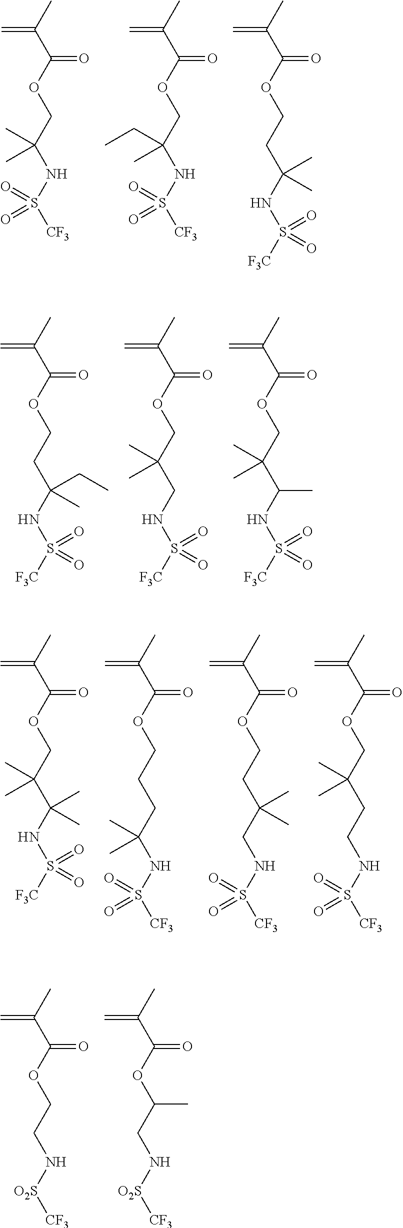

Exemplary fluorinated alcohol- and acid labile-containing monomers for use in forming the surface active polymer include a monomer of the following general formula (IV) and a monomer of the following general formula (V), respectively:

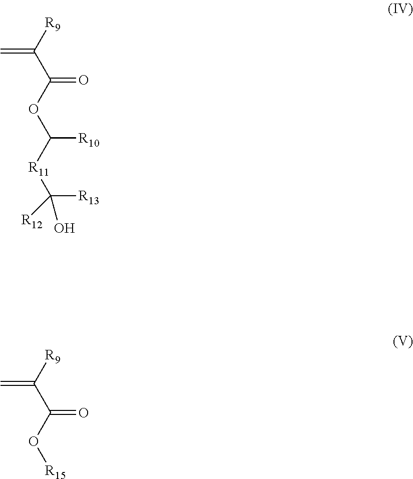

wherein: R₉ is independently hydrogen or a C1 to C6 alkyl or fluoroalkyl; R₁₀ is an optionally substituted C3 to C10 cycloalkyl such as cyclohexyl or C3 to C10 branched alkyl group, for example, an isoalkyl group such as isopropyl or isobutyl; R₁₁ is an optionally substituted C1 to C6 alkylene group, preferably methylene or ethylene; R₁₂ and R₁₃ are each independently a C1 to C4 fluoroalkyl group, preferably trifluoromethyl; and R₁₅ is an acid or base labile group, preferably having a low activation energy, for example those having a branched alkyl structure. Preferably, the surface active polymer includes polymerized units of monomers of both general formulae (III) and (IV).

Fluoroalcohol group-containing units can be present in the surface active polymer for purposes of enhancing developer solubility. It is believed that monomers of general formula (IV) allow for enhanced dynamic contact angles, for example, increased receding angle and decreased sliding angle, and for improving developer affinity and solubility. Suitable monomers of general formula (IV) include, for example, the following:

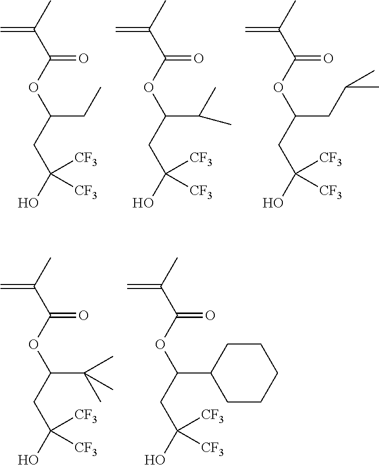

Units formed from monomers of general formula (V) containing an acid labile group are believed to provide for enhanced developer dissolution after processing the photoresist, for example, after exposure to activating radiation and post-exposure baking due to the acid-labile groups, as well as improved dynamic contact angles.

Suitable monomers of general formula (V) include, for example, the following:

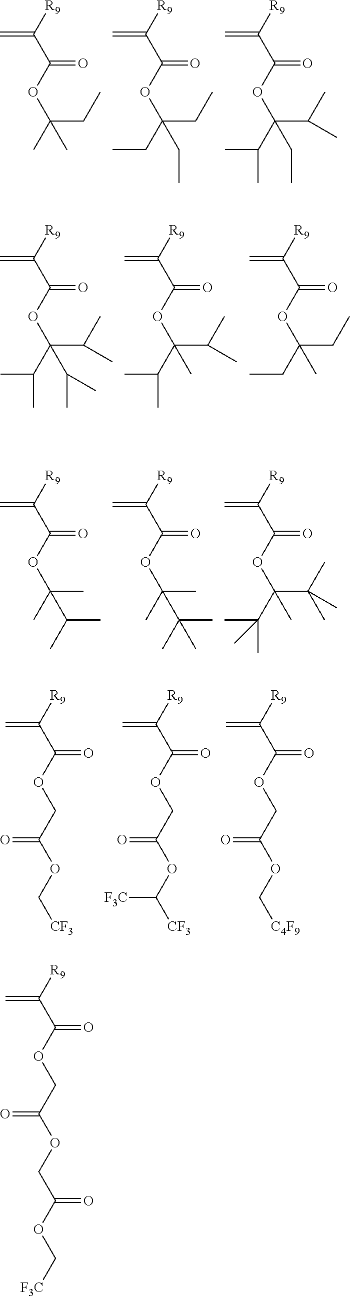

wherein R₉ is as defined above with respect to the monomer of general Formula (V).

Exemplary polymers useful as the surface active polymer include, for example, the following:

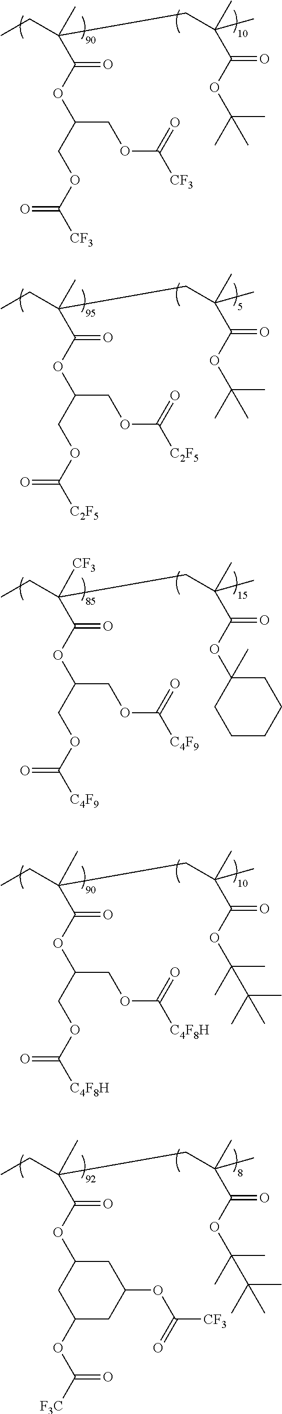

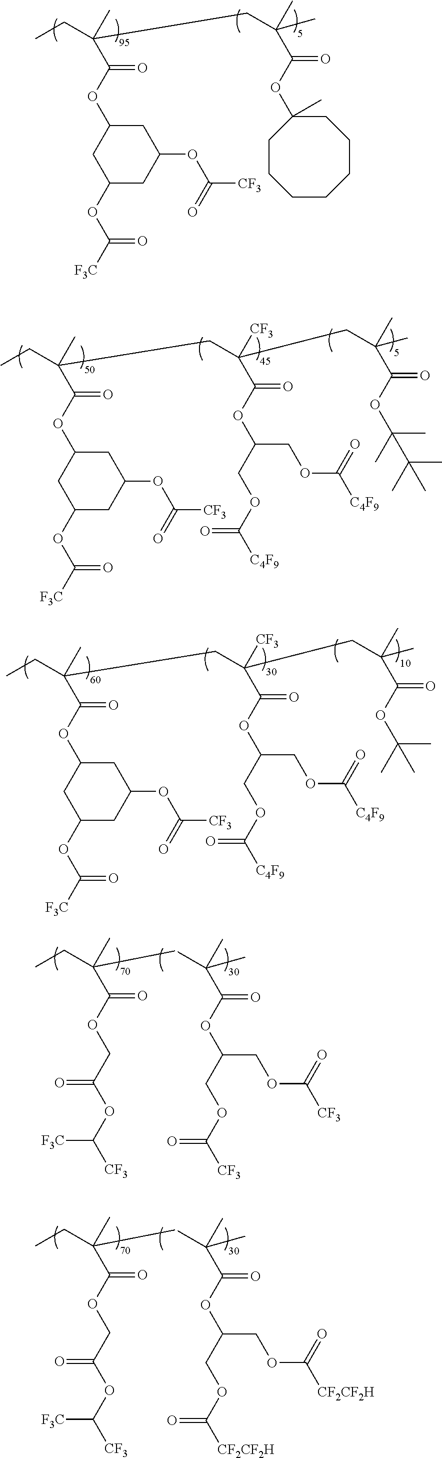

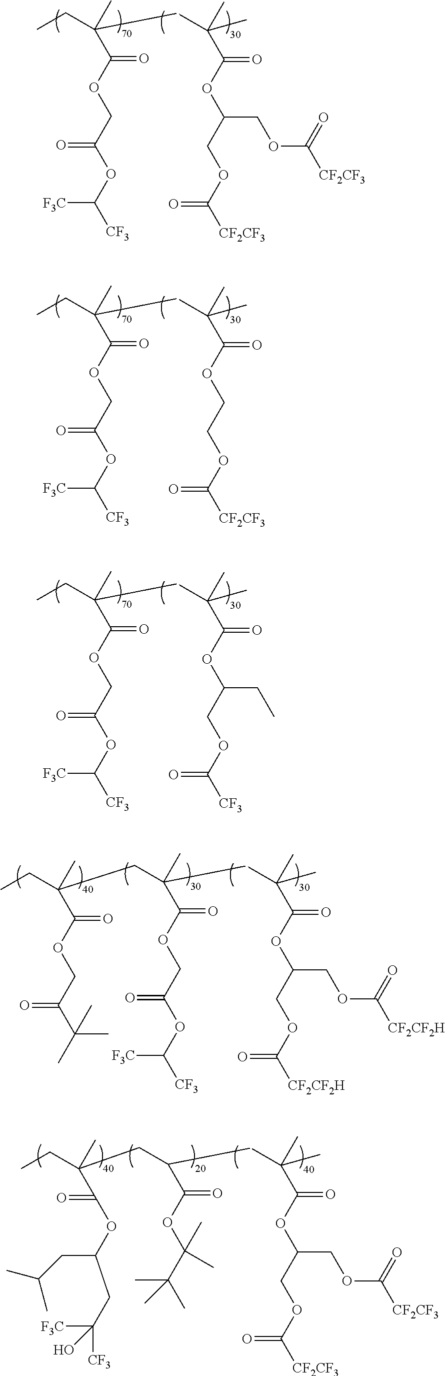

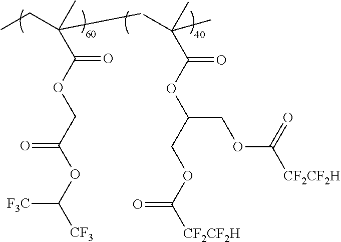

The surface active polymer lower limit for immersion lithography is generally dictated by the need to prevent leaching of the photoresist components. The surface active polymer is typically present in the compositions in an amount of from 1 to 30 wt %, more typically from 3 to 20 wt % or 5 to 15 wt %, based on total solids of the topcoat composition. The weight average molecular weight of the additive polymer is typically less than 400,000, preferably from 5000 to 50,000, more preferably from 5000 to 25,000.

Optional additional polymers can be present in the topcoat compositions. For example, an additive polymer can be provided in addition to the matrix polymer and surface active polymer, for example, for purposes of tuning the resist feature profile and/or for controlling resist top loss. The additive polymer can include one or more strong acid functional groups, for example, a sulfonic acid group. The additive polymer should be miscible with the matrix polymer while, as discussed above, generally immiscible with the surface active polymer.

Exemplary additive polymers useful in the invention include the following:

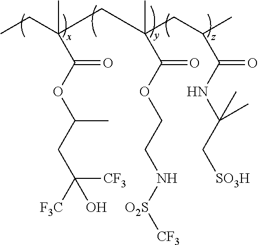

wherein x is from 0 to 89 wt %, y is from 10 to 99 wt % and z is from 1 to 5 wt % based on the weight of the polymer. In an exemplary polymer, x/y/z are 10/85/5 wt %;

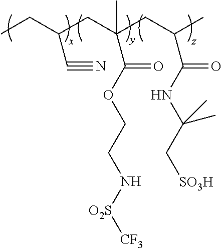

wherein x is from 5 to 20 wt %, y is from 75 to 94 wt % and z is from 1 to 5 wt % based on the weight of the polymer. In an exemplary polymer, x/y/z are 15/80/5 wt %;

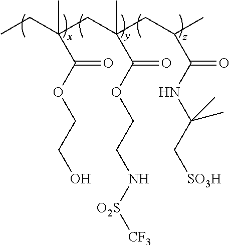

wherein x is from 5 to 20 wt %, y is from 75 to 94 wt % and z is from 1 to 5 wt % based on the weight of the polymer;

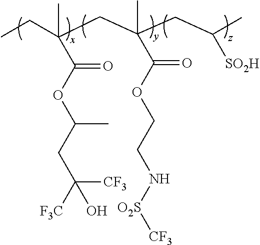

wherein x is from 0 to 89 wt %, y is from 10 to 99 wt % and z is from 1 to 5 wt % based on the weight of the polymer. In an exemplary polymer, x/y/z are 10/87/3 wt %;

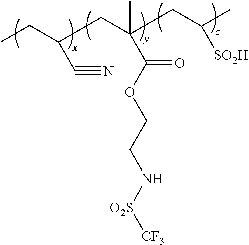

wherein x is from 5 to 20 wt %, y is from 75 to 94 wt % and z is from 1 to 5 wt % based on the weight of the polymer. In an exemplary polymer, x/y/z are 15/82/3 wt %; and

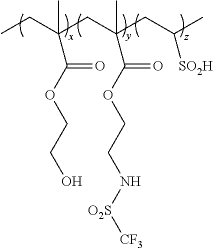

wherein x is from 5 to 20 wt %, y is from 75 to 94 wt % and z is from 1 to 5 wt % based on the weight of the polymer. In an exemplary polymer, x/y/z are 10/87/3 wt %.

The additive polymer is typically present in the compositions in an amount of from 1 to 30 wt %, more typically from 3 to 20 wt % or 5 to 15 wt %, based on total solids of the topcoat composition. The weight average molecular weight of the additive polymer is typically less than 400,000, preferably from 5000 to 50,000, more preferably from 5000 to 25,000.

Typical solvent materials to formulate and cast a topcoat composition are any which dissolve or disperse the components of the topcoat composition but do not appreciably dissolve an underlying photoresist layer. More particularly, suitable solvents to formulate a topcoat composition include one or more of, but are not limited to, alcohols such as n-butanol, alkylene glycols, such as propylene glycol. Alternatively non-polar solvents such as aliphatic and aromatic hydrocarbons, and alkyl ethers such as dodecane, isooctane and isopentyl ether may be used. Preferably, a mixture of different solvents, for example, two, three or more solvents, can be used to achieve effective phase separation of the segregating, first additive polymer from other polymer(s) in the composition and to reduce the viscosity of the formulation which allows for reduction in the dispense volume.

In an exemplary aspect, a two-solvent system or a three-solvent system can be used in the topcoat compositions of the invention. The solvent system can include, for example, a primary solvent and an additive solvent and may include a thinner solvent. The primary solvent typically exhibits excellent solubility characteristics with respect to the non-solvent components of the topcoat composition. While the desired boiling point of the primary solvent will depend on the other components of the solvent system, the boiling point is typically less than that of the additive solvent, with a boiling point of from 120 to 140° C. such as about 130° C. being typical. Suitable primary solvents include, for example, C4 to C8 n-alcohols, such as n-butanol, isobutanol, 2-methyl-1-butanol, isopentanol, 2,3-dimethyl-1-butanol, 4-methyl-2-pentanol, isohexanol and isoheptanol, isomers thereof and mixtures thereof. The primary solvent is typically present in an amount of from 30 to 80 wt % based on the solvent system.

The additive solvent is present to facilitate phase separation between the surface active polymer and other polymer(s) in the topcoat composition to facilitate a self-segregating topcoat structure. In addition, the higher boiling point additive solvent can reduce the tip drying effect during coating. It is typical for the additive solvent to have a higher boiling point than the other components of the solvent system. While the desired boiling point of the additive solvent will depend on the other components of the solvent system, a boiling point of from 170 to 200° C. such as about 190° C. is typical. Suitable additive solvents include, for example, hydroxy alkyl ethers, such as those of the formula:

R₁—O—R₂—O—R₃—OH

wherein R₁ is an optionally substituted C1 to C2 alkyl group and R₂ and R₃ are independently chosen from optionally substituted C2 to C4 alkyl groups, and mixtures of such hydroxy alkyl ethers including isomeric mixtures. Exemplary hydroxy alkyl ethers include dialkyl glycol mono-alkyl ethers and isomers thereof, for example, diethylene glycol monomethyl ether, dipropylene glycol monomethyl ether, isomers thereof and mixtures thereof. The additive solvent is typically present in an amount of from 3 to 15 wt % based on the solvent system.

A thinner solvent can be used to lower the viscosity and improve coating coverage at a lower dispensing volume. The thinner solvent is typically a poorer solvent for the non-solvent components of the composition relative to the primary solvent. While the desired boiling point of the thinner solvent will depend on the other components of the solvent system, a boiling point of from 140 to 180° C. such as about 170° C. is typical. Suitable thinner solvents include, for example, alkanes such as C8 to C12 n-alkanes, for example, n-octane, n-decane and dodecane, isomers thereof and mixtures of isomers thereof; and/or alkyl ethers such as those of the formula R₁—O—R₂, wherein R₁ and R₂ are independently chosen from C₂ to C₈ alkyl, C₂ to C₆ alkyl and C₂ to C₄ alkyl. The alkyl ether groups can be linear or branched, and symmetric or asymmetric. Particularly suitable alkyl ethers include, for example, isobutyl ether, isopentyl and isobutyl isohexyl, isomers thereof and mixtures thereof. Other suitable thinner solvents include, for example, propyl pentanoate, isopropyl pentanoate, isopropyl 3-methylbutanoate, isopropyl 2-methylbutanoate, isopropyl pivalate, isobutyl isobutyrate, 2-methylbutyl isobutyrate, 2-methylbutyl 2-methylbutanoate, 2-methylbutyl 2-methylhexanoate, 2-methylbutyl heptanoate, hexyl heptanoate, n-butyl n-butyrate, isoamyl n-butyrate and isoamyl isovalerate. The thinner solvent if used is typically present in an amount of from 10 to 70 wt % based on the solvent system.

A particularly suitable three-solvent system includes 4-methyl-2-pentanol/isopentyl ether/dipropylene glycol monomethyl ether in a ratio by weight of 49/45/6. While the exemplary solvent system has been described with respect to a three-component system, it should be clear that additional solvents may be used. For example, one or more additional primary solvent, thinner solvent, additive solvent and/or other solvent may be employed.

The topcoat compositions of the invention may comprise one or more other optional components, for example, an acid generator compound such as a photoacid generator (PAG) compound. Suitable photoacid generators are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

If employed, the one or more acid generator may be utilized in relatively small amounts in a topcoat composition, for example, 0.1 to 8 wt %, such as about 2 wt %, based on total solids of the composition. Such use of one or more acid generator compounds may favorably impact lithographic performance, particularly resolution, of the developed image patterned in an underlying resist layer.

When used in immersion lithography, preferred topcoat layer compositions will have a refractive index between that of the immersion fluid and that of the photoresist at the target exposure wavelength. Preferred topcoat composition layers typically have an index of refraction of 1.4 or greater, preferably 1.47 or greater, at 193 nm. For any particular system, the index of refraction can be tuned by changing the composition of one or more polymers of the topcoat composition, including by altering the ratio of components of a polymer blend, or composition of any of the polymer(s) of a topcoat composition. For instance, increasing the amount of organic content in a topcoat layer composition can provided increased refractive index of the layer.

The topcoat compositions of the invention may be suitably prepared by admixture of the polymers and optional components into one or more polar solvents such as those identified above or alternatively one or more non-polar solvents such as the aliphatic and aromatic hydrocarbons identified above. The viscosity of the entire composition is typically from 1.5 to 2 centipoise (cp).

### Photoresist Compositions

Photoresist compositions useful in the invention include chemically-amplified photoresist compositions comprising a matrix polymer that is acid-sensitive, meaning that as part of a layer of the photoresist composition, the polymer and composition layer undergo a change in solubility in a developer as a result of reaction with acid generated by a photoacid generator following softbake, exposure to activating radiation and post exposure bake. The resist formulation can be positive-acting or negative-acting, but is typically positive-acting. In positive-type photoresists, the change in solubility is typically brought about when acid-labile groups such as photoacid-labile ester or acetal groups in the matrix polymer undergo a photoacid-promoted deprotection reaction on exposure to activating radiation and heat treatment. Suitable photoresist compositions useful for the invention are commercially available.

For imaging at sub-200 nm wavelengths such as 193 nm, the matrix polymer is typically substantially free (e.g., less than 15 mole %) or completely free of phenyl, benzyl or other aromatic groups where such groups are highly absorbing of the radiation. Suitable polymers that are substantially or completely free of aromatic groups are disclosed in European application EP930542A1 and U.S. Pat. Nos. 6,692,888 and 6,680,159, all of the Shipley Company. Preferable acid labile groups include, for example, acetal groups or ester groups that contain a tertiary non-cyclic alkyl carbon (e.g., t-butyl) or a tertiary alicyclic carbon (e.g., methyladamantyl) covalently linked to a carboxyl oxygen of an ester of the matrix polymer.

Suitable matrix polymers further include polymers that contain (alkyl)acrylate units, preferably including acid-labile (alkyl)acrylate units, such as t-butyl acrylate, t-butyl methacrylate, methyladamantyl acrylate, methyl adamantyl methacrylate, ethylfenchyl acrylate, ethylfenchyl methacrylate, and the like, and other non-cyclic alkyl and alicyclic (alkyl)acrylates. Such polymers have been described, for example, in U.S. Pat. No. 6,057,083, European Published Applications EP01008913A1 and EP00930542A1, and U.S. Pat. No. 6,136,501. Other suitable matrix polymers include, for example, those which contain polymerized units of a non-aromatic cyclic olefin (endocyclic double bond) such as an optionally substituted norbornene, for example, polymers described in U.S. Pat. Nos. 5,843,624 and 6,048,664. Still other suitable matrix polymers include polymers that contain polymerized anhydride units, particularly polymerized maleic anhydride and/or itaconic anhydride units, such as disclosed in European Published Application EP01008913A1 and U.S. Pat. No. 6,048,662.

Also suitable as the matrix polymer is a resin that contains repeat units that contain a heteroatom, particularly oxygen and/or sulfur (but other than an anhydride, i.e., the unit does not contain a keto ring atom). The heteroalicyclic unit can be fused to the polymer backbone, and can comprise a fused carbon alicyclic unit such as provided by polymerization of a norbornene group and/or an anhydride unit such as provided by polymerization of a maleic anhydride or itaconic anhydride. Such polymers are disclosed in PCT/US01/14914 and U.S. Pat. No. 6,306,554. Other suitable heteroatom group-containing matrix polymers include polymers that contain polymerized carbocyclic aryl units substituted with one or more heteroatom (e.g., oxygen or sulfur) containing groups, for example, hydroxy naphthyl groups, such as disclosed in U.S. Pat. No. 7,244,542.

Blends of two or more of the above-described matrix polymers can suitably be used in the photoresist compositions.

Suitable matrix polymers for use in the photoresist compositions are commercially available and can be readily made by persons skilled in the art. The matrix polymer is present in the resist composition in an amount sufficient to render an exposed coating layer of the resist developable in a suitable developer solution. Typically, the matrix polymer is present in the composition in an amount of from 50 to 95 wt % based on total solids of the resist composition. The weight average molecular weight M_{w} of the matrix polymer is typically less than 100,000, for example, from 5000 to 100,000, more typically from 5000 to 15,000.

The photoresist composition further comprises a photoactive component such as a photoacid generator (PAG) employed in an amount sufficient to generate a latent image in a coating layer of the composition upon exposure to activating radiation. For example, the photoacid generator will suitably be present in an amount of from about 1 to 20 wt % based on total solids of the photoresist composition. Typically, lesser amounts of the PAG will be suitable for chemically amplified resists as compared with non-chemically amplified materials. Suitable PAGs are known in the art of chemically amplified photoresists and include, for example, those described above with respect to the topcoat composition.

Suitable solvents for the photoresist compositions include, for example: glycol ethers such as 2-methoxyethyl ether (diglyme), ethylene glycol monomethyl ether, and propylene glycol monomethyl ether; propylene glycol monomethyl ether acetate; lactates such as methyl lactate and ethyl lactate; propionates such as methyl propionate, ethyl propionate, ethyl ethoxy propionate and methyl-2-hydroxy isobutyrate; Cellosolve esters such as methyl Cellosolve acetate; aromatic hydrocarbons such as toluene and xylene; and ketones such as acetone, methylethyl ketone, cyclohexanone and 2-heptanone. A blend of solvents such as a blend of two, three or more of the solvents described above also are suitable. The solvent is typically present in the composition in an amount of from 90 to 99 wt %, more typically from 95 to 98 wt %, based on the total weight of the photoresist composition.

The photoresist compositions can also include other optional materials. For example, the compositions can include one or more of actinic and contrast dyes, anti-striation agents, plasticizers, speed enhancers, sensitizers, and the like. Such optional additives if used are typically present in the composition in minor amounts such as from 0.1 to 10 wt % based on total solids of the photoresist composition.

A preferred optional additive of the resist compositions is an added base. Suitable bases are known in the art and include, for example, linear and cyclic amides and derivatives thereof such as N,N-bis(2-hydroxyethyl)pivalamide, N,N-Diethylacetamide, N1,N1,N3,N3-tetrabutylmalonamide, 1-methylazepan-2-one, 1-allylazepan-2-one and tert-butyl 1,3-dihydroxy-2-(hydroxymethyl)propan-2-ylcarbamate; aromatic amines such as pyridine, and di-tert-butyl pyridine; aliphatic amines such as triisopropanolamine, n-tert-butyldiethanolamine, tris(2-acetoxy-ethyl) amine, 2,2′,2″,2′″-(ethane-1,2-diylbis(azanetriyl))tetraethanol, and 2-(dibutylamino)ethanol, 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate and N (2-acetoxy-ethyl) morpholine. The added base is suitably used in relatively small amounts, for example, from 0.01 to 5 wt %, preferably from 0.1 to 2 wt %, based on total solids of the photoresist composition.

The photoresists can be prepared following known procedures. For example, the resists can be prepared as coating compositions by dissolving the solid components of the photoresist in the solvent component. The desired total solids content of the photoresist will depend on factors such as the particular polymers in the composition, final layer thickness and exposure wavelength. Typically the solids content of the photoresist varies from 1 to 10 wt %, more typically from 2 to 5 wt %, based on the total weight of the photoresist composition.

### Lithographic Processing

Liquid photoresist compositions can be applied to a substrate such as by spin coating, dipping, roller coating or other conventional coating technique, with spin coating being typical. When spin coating, the solids content of the coating solution can be adjusted to provide a desired film thickness based upon the specific spinning equipment utilized, the viscosity of the solution, the speed of the spinner and the amount of time allowed for spinning.

Photoresist compositions used in accordance with the invention are suitably applied to substrates conventionally used in processes involving coating with photoresists. For example, the composition may be applied over silicon wafers or silicon wafers coated with one or more layers to be patterned, for example, one or more of metal, semiconductor and dielectric layers. Aluminum-aluminum oxide, gallium arsenide, ceramic, quartz, copper, glass substrates and the like may also be suitably employed. Photoresists also may be suitably applied over an antireflective layer. The photoresist composition is typically next soft-baked by heating to remove the solvent until the photoresist coating is tack free. The photoresist layer may alternatively be dried after the topcoat layer composition has been applied and the solvent from both the photoresist composition and topcoat composition layers substantially removed in a single thermal treatment step.

A topcoat composition of the invention can be applied over the photoresist composition by any suitable method such as described above with reference to the photoresist compositions, with spin coating being typical. The photoresist layer with topcoat composition layer is then patternwise exposed to activating radiation for the photoactive component(s) of the photoresist. In an immersion lithography system, the space between the exposure tool (particularly the projection lens) and the photoresist coated substrate is occupied by an immersion fluid, such as water optionally mixed with one or more additives such as cesium sulfate which can provide a fluid of enhanced refractive index. Typically, the immersion fluid has been treated to avoid microbubble formation.

During the exposure step (whether immersion where fluid is interposed, or non-immersion where such fluid is not interposed), the photoresist composition layer is exposed to patterned activating radiation with the exposure energy typically ranging from about 1 to 100 mJ/cm², dependent upon the exposure tool and the components of the photoresist composition. References herein to exposing a photoresist composition to radiation that is activating for the photoresist indicates that the radiation is capable of forming a latent image in the photoresist such as by causing a reaction of the photoactive component, for example, producing photoacid from a photoacid generator compound.

The photoresist composition (and topcoat composition if photosensitive) is typically photoactivated by a short exposure wavelength, for example, radiation having a wavelength of less than 300 nm such as 248 nm, 193 nm and EUV wavelengths such as 13.5 nm. Following exposure, the layer of the composition is typically baked at a temperature ranging from about 70° C. to about 160° C.

Thereafter, the film is developed, typically by treatment with an aqueous base developer chosen from: quaternary ammonium hydroxide solutions such as a tetra-alkyl ammonium hydroxide solutions, typically a 0.26N tetramethylammonium hydroxide; amine solutions such as ethyl amine, n-propyl amine, diethyl amine, di-n-propyl amine, triethyl amine, or methyldiethyl amine; alcohol amines such as diethanol amine or triethanol amine; and cyclic amines such as pyrrole or pyridine. In general, development is in accordance with procedures recognized in the art.

Following development of the photoresist coating over the substrate, the developed substrate may be selectively processed on those areas bared of resist, for example by etching or plating substrate areas bared of resist in accordance with procedures known in the art. After such processing, resist may be removed from the processed substrate using known stripping procedures. The following non-limiting examples are illustrative of the invention.

### Examples

The following monomers were used in matrix polymer, surface active polymer and additive polymer synthesis. Monomer ratios for the polymers described below are provided in mole percent (mol %) based on the polymer.

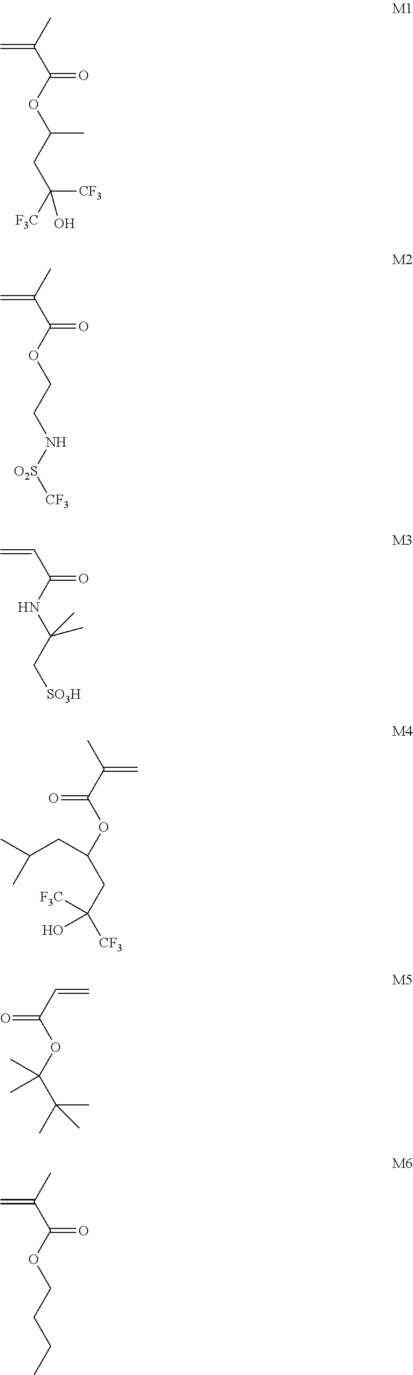

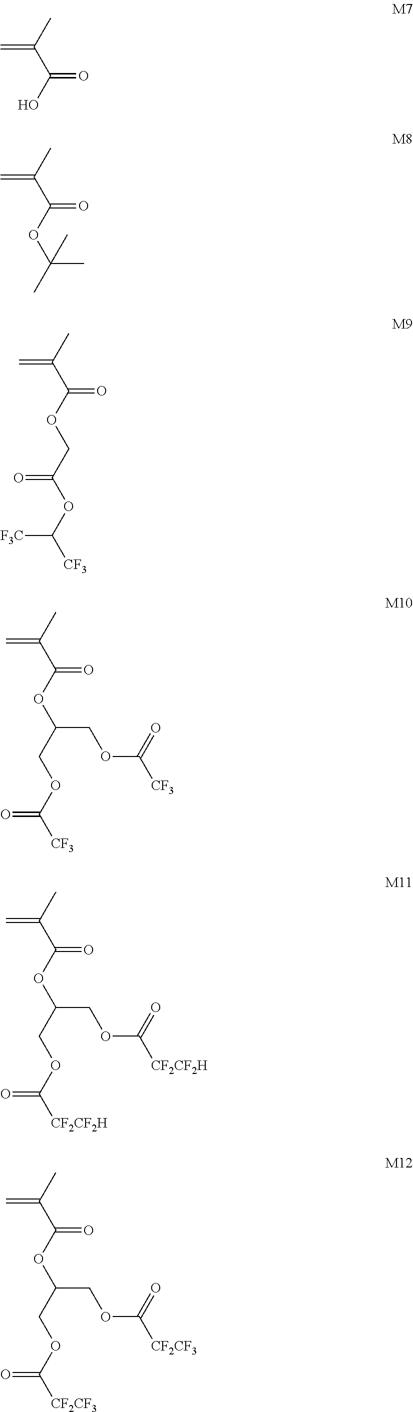

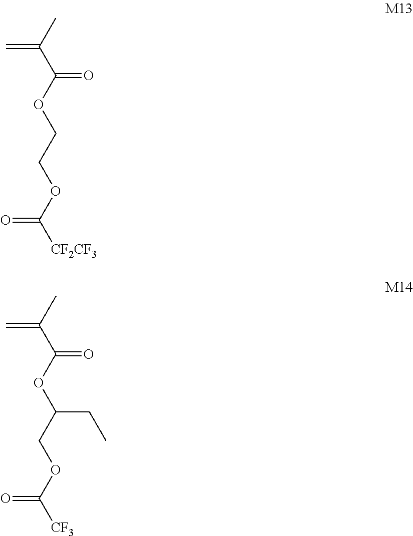

### Polymer Synthesis

### Matrix Polymer Synthesis

A monomer feed solution was prepared by combining 118.44 g 4-methyl-2-pentanol (4M2P), 78.98 g monomer M1 and 8.78 g monomer M2 in a container and agitating the mixture to dissolve the two monomers. An initiator feed solution was prepared by combining 2.63 g Vazo™ 67 free radical initiator (E. I. du Pont de Nemours and Company) and 85.06 g 4M2P in a suitable container and agitating the mixture to dissolve the initiator. 206.13 g 4M2P was introduced into a reaction vessel and the vessel was purged with nitrogen gas for 30 minutes. The reaction vessel was next heated to 97° C. with agitation. Introduction of the monomer feed solution and initiator feed solution into the reaction vessel was simultaneously started. The monomer feed solution was fed over a period of 2 hours and the initiator feed solution over a period of 3 hours. The reaction vessel was maintained at 97° C. for an additional 2 hours with agitation, and then allowed to cool to room temperature. Matrix polymer PM1 (M1/M2 (90/10); Mw=9359 Daltons; PDI=1.6) was thereby formed, as summarized in Table 1.

Matrix polymers PM2 and PM3 were synthesized employing a procedure similar to that used for PM1 using the monomers and mole percentages set forth in Table 1. Table 1 also sets forth the resulting weight average molecular weight (Mw) and polydispersity index (PDI) of the polymers.

### Surface Active Polymer Synthesis

A monomer feed solution was prepared by combining 12.45 g monomer M9, 7.55 g monomer M10 and 4.02 g Propylene Glycol Monomethyl Ether Acetate (PGMEA) in a container. The mixture was agitated to dissolve the monomers. An initiator feed solution was prepared by combining 0.60 g Wako V-601 initiator and 5.38 PGMEA in a container. The mixture was agitated to dissolve the initiator. 10.0 g PGMEA was introduced into a reaction vessel and the vessel was purged with nitrogen gas for 30 minutes. The reaction vessel was next heated to 99° C. with agitation. Introduction of the monomer feed solution and initiator feed solution into the reaction vessel was simultaneously started and continued for a period of 2 hours. The reaction vessel was maintained at 99° C. for an additional 2 hours. The reaction mixture was then allowed to cool to room temperature. Surface active polymer PS1(M9/M10 (70/30); Mw=11,905 Daltons; PDI=1.8) was thereby formed, as summarized in Table 2.

Surface active polymers PS2-PS10 were synthesized employing a procedure similar to that used for PS1 using the monomers and mole percentages set forth in Table 2. Table 2 also sets forth the resulting weight average molecular weight and polydispersity index of the polymers.

### Additive Polymer Synthesis

49.22 g monomer M3 and 49.22 g DI water were combined in a container. The mixture was agitated to dissolve monomer M3. A monomer feed solution was prepared by combining 935.15 g monomer M2, 98.44 g monomer M3 solution and 842.94 g PGME in a container and agitate the mixture to dissolve monomer M2. An initiator feed solution was prepared by combining 14.77 g Vazo™ 67 free radical initiator and 132.89 g PGME in a container, and agitating the mixture to dissolve the initiator. 975.83 g PGME was introduced into a reaction vessel and the vessel was purged with nitrogen gas for 30-60 minutes. The reaction vessel was heated to 97° C. with agitation. Once temperature of the reaction vessel stabilized at 97° C., introduction of the monomer feed solution and initiator feed solution into the reaction vessel was simultaneously started and carried out over a period of 1.5 hours. The reaction vessel was maintained at 97° C. for an additional 4 hours, and was then allowed to cool to 35° C. Vacuum was applied to the reaction vessel to remove the PGME solvent. After removing ˜40% of the reaction mixture by vacuum, vacuum was removed and the reaction mixture was allowed to cool to room temperature. The reaction mixture was added to 18 L of DI water over a period of 20 to 30 minutes with agitation in a container to precipitate the polymer out. Agitation was continued for 10 minutes after completion of addition. The resulting polymer slurry was filtered with a Buchner funnel and washed twice, each time with 2 L DI water. The resulting polymer cake was removed and dried with a vacuum dryer for 24 to 48 hours at 40° C. The dried polymer was then dissolved in 4M2P. Additive polymer PA1(M2/M3 (95/5); Mw=25,800 Daltons; PDI=2.2) was thereby formed, as summarized in Table 1.

TABLE 1

| Polymer | M1 | M2 | M3 | M6 | M7 | Mw | PDI |
|---|---|---|---|---|---|---|---|
| PM1 | 90 | 10 | | | | 9359 | 1.6 |
| PM2 | | | 3 | 57 | 40 | 27200 | 2.3 |
| PM3 | | | | 48 | 52 | 17300 | 1.9 |
| PA1 | | 95 | 5 | | | 25800 | 2.2 |

TABLE 2

| Polymer | M2 | M4 | M5 | M8 | M9 | M10 | M11 | M12 | M13 | M14 | Mw | PDI |
|---|---|---|---|---|---|---|---|---|---|---|---|---|
| PS1 | | | | | 70 | 30 | | | | | 11905 | 1.8 |
| PS2 | | | | | 70 | | 30 | | | | 10353 | 1.8 |
| PS3 | | | | | 70 | | | 30 | | | 11254 | 1.7 |
| PS4 | | | | | 70 | | | | 30 | | 12003 | 1.8 |
| PS5 | | | | | 70 | | | | | 30 | 10995 | 1.8 |
| PS6 | | | | 40 | 30 | | 30 | | | | 14824 | 1.9 |
| PS7 | | 40 | 20 | | | | | 40 | | | 12023 | 1.8 |
| PS8 | | | | | 60 | | 40 | | | | 10556 | 1.9 |
| PS9 | | | | | 50 | | 50 | | | | 13002 | 1.9 |
| PS10 | 20 | 55 | 25 | | | | | | | | 11923 | 1.8 |

### Topcoat Composition Formulation

Topcoat compositions of the invention were prepared by admixing the components in the amounts set forth in Table 3.

TABLE 3

| Ex. | MP | | AP | | SAP | | 4M2P | IAE | DPM | IBIB |
|---|---|---|---|---|---|---|---|---|---|---|
| Comp. 1 | PM1 | 1.34 | PA1 | 0.53 | PS10 | 0.09 | 51.25 | 46.79 | | |
| Comp. 2 | PM1 | 1.71 | PA1 | | PS10 | 0.07 | 51.34 | 46.88 | | |
| Comp. 3 | PM1 | 1.24 | PA1 | 0.49 | PS10 | 0.08 | 98.03 | | | |
| 1 | PM1 | 1.71 | PA1 | 0.68 | PS1 | 0.11 | 65.13 | | 4.47 | 27.91 |
| 2 | PM1 | 2.17 | | | PS2 | 0.08 | 65.13 | | 4.47 | 27.91 |
| 3 | PM3 | 1.71 | PA1 | 0.68 | PS3 | 0.11 | 65.13 | | 4.47 | 27.91 |
| 4 | PM1 | 1.34 | PA1 | 0.53 | PS4 | 0.09 | 51.25 | 42.32 | 4.47 | |
| 5 | PM1 | 1.34 | PA1 | 0.53 | PS5 | 0.09 | 51.25 | 42.32 | 4.47 | |
| 6 | PM1 | 2.17 | | | PS6 | 0.08 | 65.13 | | 4.47 | 27.91 |
| 7 | PM3 | 1.71 | PA1 | 0.68 | PS7 | 0.11 | 65.13 | | 4.47 | 27.91 |
| 8 | PM1 | 2.17 | | | PS2 | 0.08 | 65.13 | | 4.47 | 27.91 |
| 9 | PM1 | 2.17 | | | PS2 | 0.08 | 65.13 | | 4.47 | 27.91 |

MP = Matrix Polymer;
SAP = Surface Active Polymer;
AP = Additive Polymer;
4M2P = 4-Methyl-2-Pentanol;
IAE = Isoamyl Ether;
DPM—Dipropylene Glycol Methyl Ether;
IBIB—Isobutyl Isobutyrate;
All values in grams (g).

### Contact Angle Measurement

The topcoat compositions were coated on EPIC™ 2096 positive photoresist (Rohm and Haas Electronic Materials) to a thickness of 1100 Å and then baked at 90° C. for 60 seconds. Static contact angle (SCA), receding contact angle (RCA), advancing contact angle (ACA) and sliding angle (SA) with respect to DI water were measured for each sample. Static and dynamic contact angles were measured using a KRUSS drop shape analyzer model 100. For dynamic contact angle measurement, the droplet size of DI water was 50 μl (microliter), and the wafer stage tilting rate was 1 unit/sec. Once a water droplet was placed on a test wafer surface, tilting of the wafer stage began immediately. During wafer stage tilting, video of the droplet was taken at a rate of 20 frames per second until the droplet slid away from its original location. Each frame in the video was then analyzed, and the image of the droplet on the frame when the droplet just started to slide was used to determine the dynamic contact angles (receding and advancing) by their corresponding tangent lines. Sliding angle is the wafer stage tilting angle corresponding to the frame when the droplet just started to slide. In static contact angle measurement, water droplet was 2.5 μl and placed on the test wafer surface without tilting. The contact angle was determined by the tangent lines on both sides of the droplet. The reported static contact angle was the average of the contact angles from left and right sides of the droplet. The results are shown in Table 4.

TABLE 4

| Ex. | SCA | RCA | ACA | SA |
|---|---|---|---|---|
| Comp. 1 | 86 | 70 | 95 | 19 |
| Comp. 2 | 86 | 71 | 93 | 18 |
| Comp. 3 | 86 | 70 | 92 | 22 |
| 1 | 90 | 73 | 95 | 25 |
| 2 | 99 | 75 | 101 | 35 |
| 3 | 100 | 78 | 102 | 32 |
| 4 | 93 | 73 | 96 | 28 |
| 5 | 96 | 75 | 99 | 30 |
| 6 | 96 | 72 | 101 | 35 |
| 7 | 99 | 82 | 101 | 30 |
| 8 | 99 | 77 | 98 | 32 |
| 9 | 95 | 72 | 95 | 27 |

### Immersion Lithography

Silicon wafers are spin-coated with antireflectant material to form a bottom antireflective coating (BARC). The wafers are softbaked and a positive photoresist layer is coated on the BARC-coated wafers and soft-baked. Topcoat compositions of Examples 1-9 are coated over the photoresist and soft-baked. The wafers are exposed through a mask on an immersion scanner. The exposed wafers are post-exposure baked and developed with TMAH developer (2.38%) to form resist patterns.

What is claimed is:

1. A topcoat composition, comprising:
a matrix polymer;
a surface active polymer comprising a first unit comprising a group of the following general formula (I): 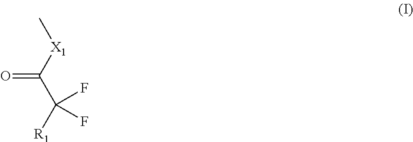
wherein R₁ represents H, F, C1 to C8 alkyl or C1 to C8 fluoroalkyl, optionally comprising one or more heteroatom; X₁ represents oxygen, sulfur or NR₂, wherein R₂ is chosen from hydrogen and optionally substituted C1 to C10 alkyl; and
a solvent;
wherein the surface active polymer is present in the composition in an amount less than the matrix polymer, and the surface active polymer has a lower surface energy than a surface energy of the matrix polymer.

2. The topcoat composition of claim 1, wherein the first unit is of the following general formula (II): 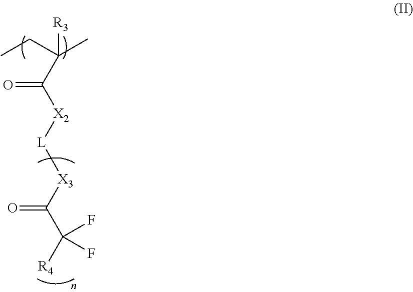
wherein: R₃ represents H, F, C1 to C4 alkyl or C1 to C4 fluoroalkyl; R₄ independently represents H, F, C1 to C8 alkyl or C1 to C8 fluoroalkyl, optionally including one or more heteroatom; X₂ and X₃ independently represent oxygen, sulfur or NR₅, wherein R₅ is chosen from hydrogen and optionally substituted C1 to C10 alkyl; L represents an (n+1) valent linker; and n is an integer from 1 to 5.

3. The topcoat composition of claim 2, wherein n is 1.

4. The topcoat composition of claim 2, wherein n is 2.

5. The topcoat composition of any of claims 2 to 4, wherein X₂ and X₃ are oxygen.

6. The topcoat composition of claim 2, wherein the first unit is formed from a monomer chosen from the following monomers:

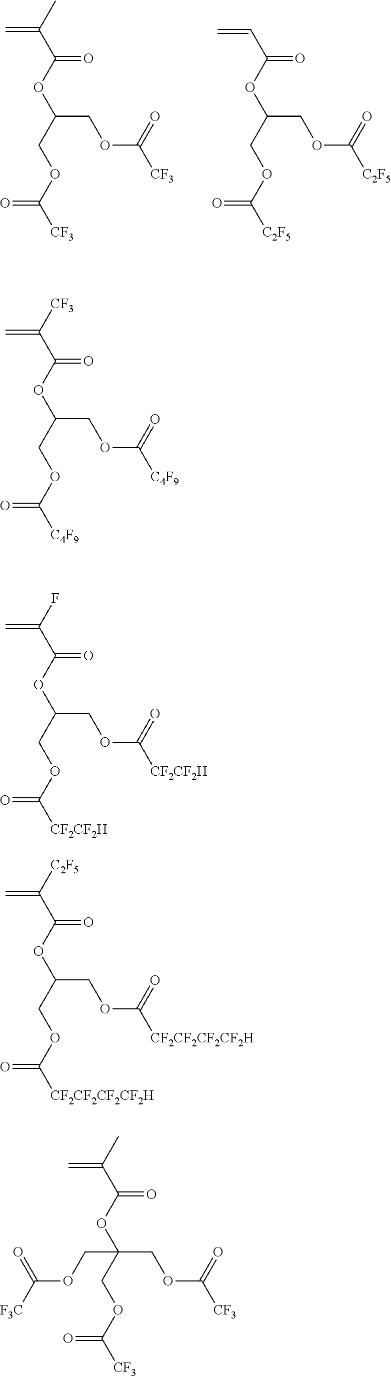

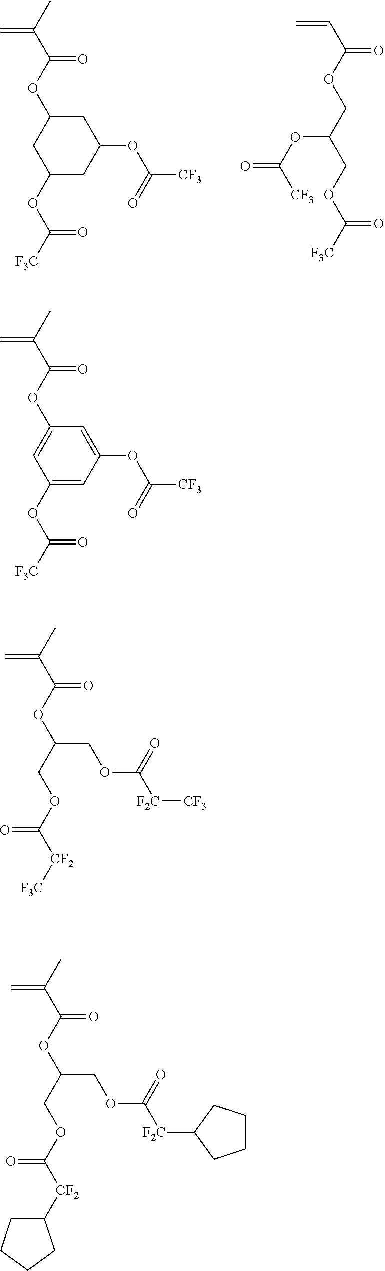 [SMILES: C=C(C)C(=O)OC1CC(OC(=O)C(F)(F)F)CC(OC(=O)C(F)(F)F)C1 ; C=CC(=O)OCC(COC(=O)C(F)(F)F)OC(=O)C(F)(F)F ; C=C(C)C(=O)Oc1cc(OC(=O)C(F)(F)F)cc(OC(=O)C(F)(F)F)c1 ; C=C(C)C(=O)OC(COC(=O)C(F)(F)C(F)(F)F)COC(=O)C(F)(F)C(F)(F)F ; C=C(C)C(=O)OC(COC(=O)C(F)(F)C1CCCC1)COC(=O)C(F)(F)C1CCCC1]

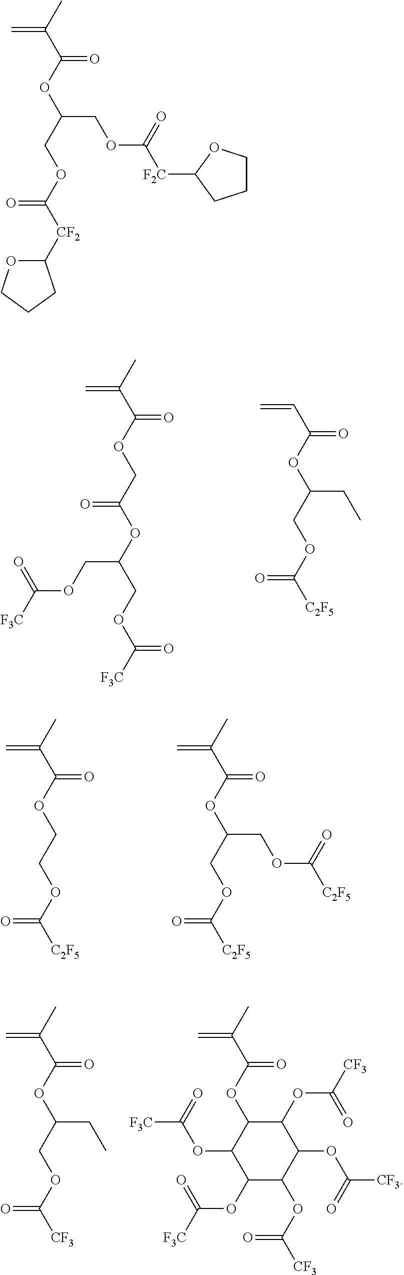

7. The topcoat composition of any of claims 1 to 6, wherein the surface active polymer further comprises a second unit comprising a group chosen from one or more of fluorinated sulfonamide groups, fluorinated alcohol groups, fluorinated ester groups and acid labile leaving groups.

8. The topcoat composition of any of claims 1 to 7, wherein the surface active polymer is present in an amount of from 1 to 30 wt % based on total solids of the topcoat composition.

9. A pattern-forming method, comprising:
(a) forming a photoresist layer over a substrate;
(b) forming a topcoat layer over the photoresist layer, wherein the topcoat layer is formed from a topcoat composition of any of claims 1 to 8;
(c) exposing the topcoat layer and the photoresist layer to activating radiation; and
(d) contacting the exposed topcoat layer and photoresist layer with a developer to form a photoresist pattern.

10. The method of claim 9, wherein the exposing is conducted by immersion lithography.
